(19) United States
(12) Patent Application Publication
(10) Pub. No.: US 2013/0240937 A1
(43) Pub. Date: Sep. 19, 2013

(54) SEMICONDUCTOR LIGHT-EMITTING DIODE CHIP, LIGHT-EMITTING DEVICE, AND MANUFACTURING METHOD THEREOF

(71) Applicants: Seung Wan Chae, Yongin-si (KR); Tae Hun Kim, Anyang-si (KR); Su Yeol Lee, Seongnam-si (KR); Jin Bock Lee, Osan-si (KR); Jin Hwan Kim, Goyang-si (KR); Seung Jae Lee, Cheonan-si (KR); Bo Kyoung Kim, Suwon-si (KR); Jong Ho Lee, Seoul (KR)

(72) Inventors: Seung Wan Chae, Yongin-si (KR); Tae Hun Kim, Anyang-si (KR); Su Yeol Lee, Seongnam-si (KR); Jin Bock Lee, Osan-si (KR); Jin Hwan Kim, Goyang-si (KR); Seung Jae Lee, Cheonan-si (KR); Bo Kyoung Kim, Suwon-si (KR); Jong Ho Lee, Seoul (KR)

(73) Assignee: SAMSUNG ELECTRONICS CO., LTD., Suwon-si, Gyeonngi-do (KR)

(21) Appl. No.: 13/820,459

(22) PCT Filed: Sep. 1, 2011
(86) PCT No.: PCT/KR11/06505

§ 371 Date: Jun. 3, 2013

(30) Foreign Application Priority Data
Sep. 1, 2010 (KR) 10-2010-0085705
Sep. 1, 2011 (KR) 10-2011-0088613

(51) Int. Cl. H01L 33/46

(52) U.S. Cl. CPC H01L 33/46
USPC 257/98; 438/29

(57) ABSTRACT

There is provided a semiconductor light emitting diode (LED) chip including: a semiconductor light emitting diode unit including a light-transmissive substrate, and a first conductivity-type semiconductor layer, an active layer, and a second conductivity-type semiconductor layer sequentially formed on an upper surface of the light-transmissive substrate; a rear reflective laminate including an auxiliary optical layer formed on a lower surface of the light-transmissive substrate and made of a material having a predetermined refractive index and a metal reflective film formed on a lower surface of the auxiliary optical layer; and a bonding laminate provided on a lower surface of the rear reflective laminate and including a bonding metal layer made of a eutectic metal material and an anti-diffusion film formed to prevent diffusion of elements between the bonding metal layer and the metal reflective film.

### BACKGROUND OF THE INVENTION

1. Field of the Invention

The present invention relates to a semiconductor light emitting diode chip, a light emitting device, and a manufacturing method thereof.

2. Description of the Related Art

A light emitting diode (LED), a semiconductor device that converts electrical energy into optical energy, is made of a compound semiconductor material emitting light having a particular wavelength according to an energy band gap. Applications of LEDs have extended from optical communications and displays, such as a mobile device displays, computer monitors, and planar light sources, such as a backlight units (BLUs) for LCDs, to general illumination devices.

In various fields of LED application, heat dissipation measures to manage a high heating value of LEDs are required. In particular, in the case of increasing a current applied to individual LEDS as a method for reducing a usage amount of LEDs, resolving a problem of an increasing heating value is posed as an important issue.

In order to dissipate heat, an infinite heat dissipation plate, or the like, may be installed outside an LED on a module to perform cooling through forced convection. However, the attachment of the additional element may increase a volume of a product, resulting in an increase in product costs.

Meanwhile, a semiconductor layer constituting an LED may have a refractive index greater than that of an ambient atmosphere, an encapsulating material, or a substrate, so that a critical angle determining an incident angle range in which light is emitted is reduced, and as a result, a considerable amount of light generated by an active layer may be totally internally reflected so as to propagate in an undesired direction or be lost during the total reflection process, reducing light extraction efficiency. In association therewith, a method for improving substantial luminance by increasing a quantity of light proceeding in a desired direction is required.

### SUMMARY OF THE INVENTION

In the art, a method for effectively improving thermal resistance in an interface between a semiconductor light emitting diode (LED) chip and an element to which the semiconductor LED chip bonded is required. Also, a method for employing an excellent reflective structure guaranteeing a high degree of reflectivity to improve luminance of an LED chip is required.

According to an aspect of the present invention, there is provided a semiconductor light emitting diode (LED) chip including: a semiconductor light emitting diode unit including a light-transmissive substrate, and a first conductivity-type semiconductor layer, an active layer, and a second conductivity-type semiconductor layer sequentially formed on an upper surface of the light-transmissive substrate; a rear reflective laminate including an auxiliary optical layer formed on a lower surface of the light-transmissive substrate and made of a material having a predetermined refractive index and a metal reflective film formed on a lower surface of the auxiliary optical layer; and a bonding laminate provided on a lower surface of the rear reflective laminate and including a bonding metal layer made of a eutectic metal material and an anti-diffusion film formed to prevent diffusion of elements between the bonding metal layer and the metal reflective film.

The eutectic metal material of the bonding metal layer may contain at least one among gold (Au), silver (Ag), and tin (Sn). The eutectic metal material of the bonding metal layer may include Au—Sn.

The metal reflective film may include aluminum (Al), silver (Ag), or a mixture thereof. The anti-diffusion film may include a material selected from among chromium (Cr), gold (Au), TiW, TiN, and a combination thereof.

The auxiliary optical layer may be made of an oxide or a nitride including an element selected from the group consisting of silicon (Si), zirconium (Zr), tantalum (Ta), titanium (Ti), indium (In), tin (Sn), magnesium (Mg), and aluminum (Al).

The auxiliary optical layer may have a distributed Bragg reflector (DBR) structure in which two types of dielectric thin films having different refractive indices are alternately laminated. The two types of dielectric thin films may be made of an oxide or a nitride including an element selected from the group consisting of silicon (Si), zirconium (Zr), tantalum (Ta), titanium (Ti), indium (In), tin (Sn), magnesium (Mg), and aluminum (Al), respectively.

According to another aspect of the present invention, there is provided a semiconductor light emitting device including a semiconductor light emitting diode (LED) chip and a support supporting the semiconductor LED chip, wherein the semiconductor LED chip includes a semiconductor light emitting diode unit including a light-transmissive substrate, and a first conductivity-type semiconductor layer, an active layer, and a second conductivity-type semiconductor layer sequentially formed on an upper surface of the light-transmissive substrate; a rear reflective laminate including an auxiliary optical layer formed on a lower surface of the light-transmissive substrate and made of a material having a predetermined refractive index and a metal reflective film formed on a lower surface of the auxiliary optical layer; and a bonding laminate provided on a lower surface of the rear reflective laminate and including a bonding metal layer having an interface fusion-bonded to the support and made of a eutectic metal material and an anti-diffusion film formed to prevent diffusion of elements between the bonding metal layer and the metal reflective film.

According to another aspect of the present invention, there is provided a method for manufacturing a semiconductor light emitting diode (LED) chip, including: preparing a light-transmissive wafer and a semiconductor laminate including a first conductivity-type semiconductor layer, an active layer, and a second conductivity-type semiconductor layer sequentially formed on an upper surface of the light-transmissive wafer; providing a support substrate on the semiconductor laminate; polishing a lower surface of the light-transmissive wafer to reduce a thickness of the light-transmissive wafer; irradiating a laser beam to form cracks allowing the light-transmissive wafer and the semiconductor laminate to be separated into device units; forming a metal reflective film on a lower surface of the light-transmissive wafer after the irradiating a laser beam; and separating the light-transmissive wafer and the semiconductor laminate by using the cracks.

The foregoing technical solutions do not fully enumerate all of the features of the present invention.

The foregoing and other objects, features, aspects and advantages of the present invention will become more apparent from the following detailed description of the present invention when taken in conjunction with the accompanying drawings.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view illustrating a semiconductor light emitting diode (LED) chip according to an embodiment of the present invention;

FIG. 2 is a graph showing a change in reflectivity according to thickness of an auxiliary optical layer made of SiO₂ in a rear reflective layer employed in an embodiment of the present invention;

FIG. 3 is a graph showing comparison of thermal conduction rates of Ag—Sn and silicon bonded resin preferably used as a bonding metal layer according to an embodiment of the present invention;

FIG. 4 is a cross-sectional view illustrating a semiconductor light emitting diode (LED) chip according to another embodiment of the present invention;

FIG. 5 is a view illustrating a light emitting device employing the semiconductor LED chip illustrated in FIG. 4;

FIG. 6 is a graph showing a change in reflectivity over incident angle of a reflective structure including only a distributed Bragg reflector (DBR);

FIG. 7 is a graph showing a change in reflectivity over incident angle of a reflective structure including a distributed Bragg reflector (DBR) plus a metal reflective film (Al); and

FIGS. 8 and 9 are cross-sectional views sequentially showing processes of an example of a method for manufacturing an LED chip according to an embodiment of the present invention.

### DETAILED DESCRIPTION OF THE PREFERRED EMBODIMENT

Embodiments of the present invention will now be described in detail with reference to the accompanying drawings.

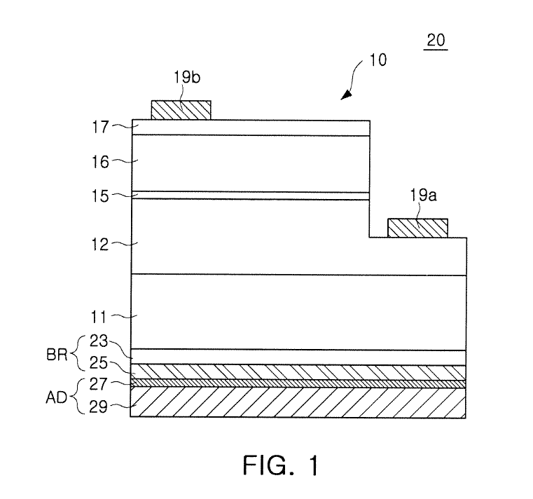

FIG. 1 is a cross-sectional view illustrating a semiconductor light emitting diode (LED) chip according to an embodiment of the present invention.

As illustrated in FIG. 1, a semiconductor LED chip includes an LED structure 10 including an n-type semiconductor layer 12, an active layer 15, and a p-type semiconductor layer 16 sequentially formed on a substrate 11.

The substrate 11 may be a light-transmissive substrate such as a sapphire substrate. The n-type semiconductor layer 12, the active layer 15, and the p-type semiconductor layer 16 may be nitride semiconductor layers.

An n-sided electrode 19a is formed in a region of an upper surface of the n-type semiconductor layer 12 exposed through mesa etching, and a transparent electrode layer 17 and a p-sided electrode 19b are sequentially formed on an upper surface of the p-type semiconductor layer 16. The active layer 15 may have a multi-quantum well (MQW) structure including a plurality of quantum barrier layers and a plurality of quantum well layers.

In the present embodiment, a rear reflective laminate BR is formed on a lower surface of the light-transmissive substrate 11 and serves to change a path of light, which proceeds to the substrate, in a desired direction (i.e., in a direction in which an epitaxial layer is positioned).

As illustrated in FIG. 1, the rear reflective laminate BR may include an auxiliary optical layer 23 made of a material having a predetermined refractive index and a metal reflective film 25 formed on a lower surface of the auxiliary optical layer 23.

The auxiliary optical layer 23 employed in the present embodiment may be made of a material having a predetermined refractive index while having light transmittance. For example, the auxiliary optical layer 23 may be made of an oxide or a nitride including an element selected from the group consisting of silicon (Si), zirconium (Zr), tantalum (Ta), titanium (Ti), indium (In), tin (Sn), magnesium (Mg), and aluminum (Al). Meanwhile, the metal reflective film 25 may be made of aluminum (Al), silver (Ag), or a mixture thereof.

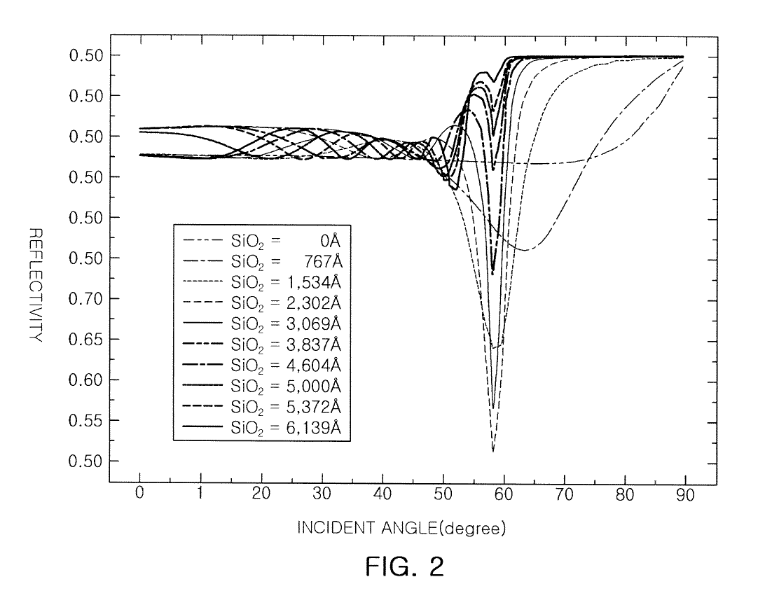

By employing such a reflective structure, i.e., by forming a dielectric layer having a predetermined refractive index before the metal reflective film 25 in a direction in which light is made incident, reflectivity may be enhanced. This will be described in detail with reference to Table 1 together with FIG. 2.

FIG. 2 is a graph showing measurement of differences in reflectivity over incident angle according to thicknesses of an SiO₂ film as the auxiliary optical layer in the configuration including the auxiliary optical layer and the metal reflective film (e.g., an aluminum film) (having a thickness of 2000 Å sequentially formed on a lower surface of the sapphire substrate. Table 2 below shows results of producing an average reflectivity according to a change in the thickness of the SiO₂ film based on reflectivity over incident angle shown in FIG. 2.

TABLE 1

| Thickness of SiO₂ film (Å) | Average reflectivity (%) |
|---|---|
| None | 88.14 |
| 767 | 88.46 |
| 1534 | 88.81 |
| 2302 | 90.93 |
| 3069 | 91.30 |
| 3837 | 92.78 |
| 4604 | 92.75 |
| 5000 | 92.98 |
| 5372 | 93.36 |
| 6139 | 92.91 |

As shown in Table 1 together with FIG. 2, it can be seen that reflectivity is enhanced on the whole when a reflective index layer (i.e., the auxiliary optical layer) interposed between the metal reflective film and the substrate is introduced. Also, generally, 90% or more of reflectivity was obtained when the reflective index layer had a thickness of about 2000 Å.

It can be seen that, in the case of the sapphire substrate, when only the metal reflective film made of aluminum was used, the reflectivity was approximately 88.14%, but when the SiO₂ layer having a thickness of about 5372 Å was interposed between the aluminum layer and the sapphire substrate, reflectivity was enhanced to approximately 93.36%.

In this manner, the rear reflective structure BR proposed in the present embodiment provides a higher degree of reflectivity than that of the case of using the metal reflective film alone, effectively contributing to substantial enhancement of luminance.

In addition, the semiconductor LED chip 20 according to the present embodiment includes the bonding laminate AD formed on a lower surface of the rear reflective structure BR.

The bonding laminate AD includes a bonding metal layer 27 made of a eutectic metal material and an anti-diffusion film 29 formed to prevent diffusion of elements between the bonding metal layer 27 and the metal reflective film 25.

A eutectic metal material of the bonding metal layer 27 may include at least one of gold (Au), silver (Ag), and tin (Sn). Preferably, the eutectic metal material of the bonding metal layer 27 may include Au—Sn.

In the case of analyzing internal thermal resistance distribution of the LED 10, an interface between the chip and the package may be considered to be a portion that greatly dominates heat dissipation efficiency. Low resistance in the interface may be implemented by using a eutectic alloy, instead of using a general bonding resin such as a silicon resin.

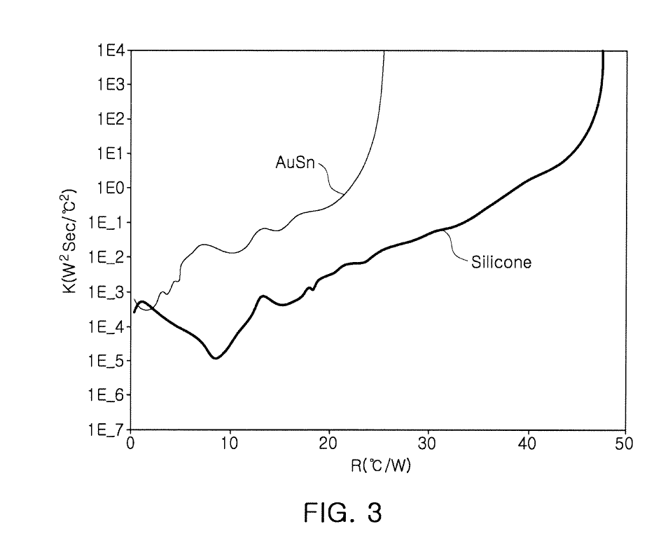

As illustrated in FIG. 3, the Au—Sn eutectic metal has a high thermal conduction rate relative to a silicon resin, so heat generated by the LED chip 20 can be effectively dissipated through the eutectic bonding interface in contact with the package.

A constituent element of the bonding metal layer 27 made of a eutectic metal may be diffused to the adjacent metal reflective film 25 (e.g., Sn is diffused according to a temperature and an electric field) to degrade reflectivity characteristics. The anti-diffusion film 29 serves to prevent loss of the reflectivity characteristics due to undesired diffusion. The anti-diffusion film 29 may be made of a material selected from the group consisting of chromium (Cr), gold (Au), TiW, TiN, and a combination thereof.

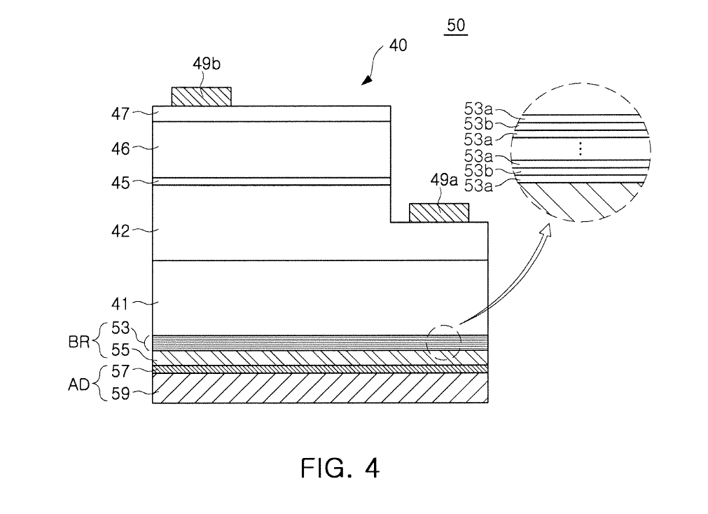

FIG. 4 is a cross-sectional view illustrating a semiconductor light emitting diode (LED) chip according to another embodiment of the present invention.

As illustrated in FIG. 4, a semiconductor LED chip includes an LED structure 40 including an n-type semiconductor layer 42, an active layer 45, and a p-type semiconductor layer 46 sequentially formed on a substrate 41.

The substrate 41 may be a light-transmissive substrate such as a sapphire substrate. The n-type semiconductor layer 42, the active layer 45, and the p-type semiconductor layer 46 may be nitride semiconductor layers.

Similar to the configuration illustrated in FIG. 1, an n-sided electrode 49a is formed in a region of an upper surface of the n-type semiconductor layer 42 exposed through mesa etching, and a transparent electrode layer 47 and a p-sided electrode 49b are sequentially formed on an upper surface of the p-type semiconductor layer 46. The active layer 45 may have a multi-quantum well (MQW) structure including a plurality of quantum barrier layers and a plurality of quantum well layers.

As illustrated in FIG. 4, the semiconductor LED chip 50 includes a rear reflective laminate BR having an auxiliary optical layer 53 made of a material having a predetermined refractive index and a metal reflective film 55 formed on a lower surface of the auxiliary optical layer 53.

Unlike the embodiment illustrated in FIG. 1, the auxiliary optical layer 53 employed in the present embodiment may have a DBR structure in which two types of dielectric thin films 53a and 53b having different refractive indices are alternately laminated. The two types of dielectric thin films 53a and 53b may be made of an oxide or a nitride including an element selected from the group consisting of silicon (Si), zirconium (Zr), tantalum (Ta), titanium (Ti), indium (In), tin (Sn), magnesium (Mg), and aluminum (Al).

The auxiliary optical layer 53 having a dielectric DBR structure employed in the present embodiment may have high reflectivity of 90% or more or in addition, 95% or more by itself.

The semiconductor LED chip 50 according to the present embodiment may include a bonding laminate AD formed on a lower surface of the rear reflective structure BR. The bonding laminate AD may include a bonding metal layer 57 made of a eutectic metal material and an anti-diffusion film 59 formed to prevent diffusion of elements between the bonding metal layer 57 and the metal reflective film 55.

A eutectic metal material of the bonding metal layer 57 may include at least one of gold (Au), silver (Ag), and tin (Sn). Preferably, the eutectic metal material of the bonding metal layer 57 may include Au—Sn.

The anti-diffusion film 49 serves to prevent loss of reflectivity characteristics due to undesired diffusion of a constituent element of the bonding metal layer 57. The anti-diffusion film 59 may be made of a material selected from the group consisting of chromium (Cr), gold (Au), TiW, TiN, and a combination thereof.

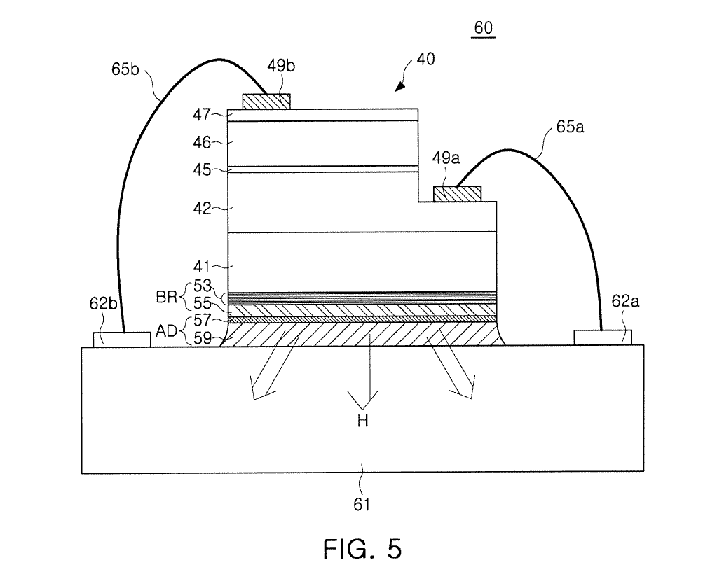

FIG. 5 is a view illustrating a light emitting device employing the semiconductor LED chip illustrated in FIG. 4.

Referring to FIG. 5, a semiconductor light emitting device 60 includes the LED chip 50 illustrated in FIG. 4 and a support 61.

The support 61 employed in the present embodiment may have a structure including lead frames 62a and 62b for a connection to an external circuit. The respective lead frames 62a and 62b may be electrically connected to the LED chip 50 by a means such as wires 65a and 65b.

In the present embodiment, the LED chip 50 may be bonded to the support 61 through fusion bonding 65. As described above, since thermal resistance is lowered by using the bonding metal layer 57 made of a eutectic metal material in the interface between the chip 50 and the package (i.e., the “support” in the present embodiment) which greatly dominates heat dissipation efficiency, heat H generated by the LED chip 50 can be effectively dissipated.

The improvement of the heat dissipation efficiency can be advantageously employed in a high output semiconductor light emitting device with which heat dissipation function weighs especially.

The auxiliary optical layer 53 employed in the embodiment illustrated in FIG. 4 is known to have a high degree of reflectivity, but it has a limitation in that excellent reflectivity characteristics cannot be expected unless it is used together with a metal reflective film made of silver (Ag), aluminum (Al), or the like, having a high degree of reflectivity, as well as being used alone. The relevant content, i.e., the effect of the combination of the DBR and the metal reflective film will be described in detail through two types of experiment examples hereinafter.

### Experiment Example 1

### Effect of DBR+Metal Reflective Film

In order to ascertain the effect of improving reflectivity characteristics of the combination of DBR and metal reflective film employed in the present embodiment, first, two DBR reflective structures were fabricated by alternately depositing twenty-four SiO₂ thin films and twenty-four Si₃N₄ thin films, totaling forty-eight layers.

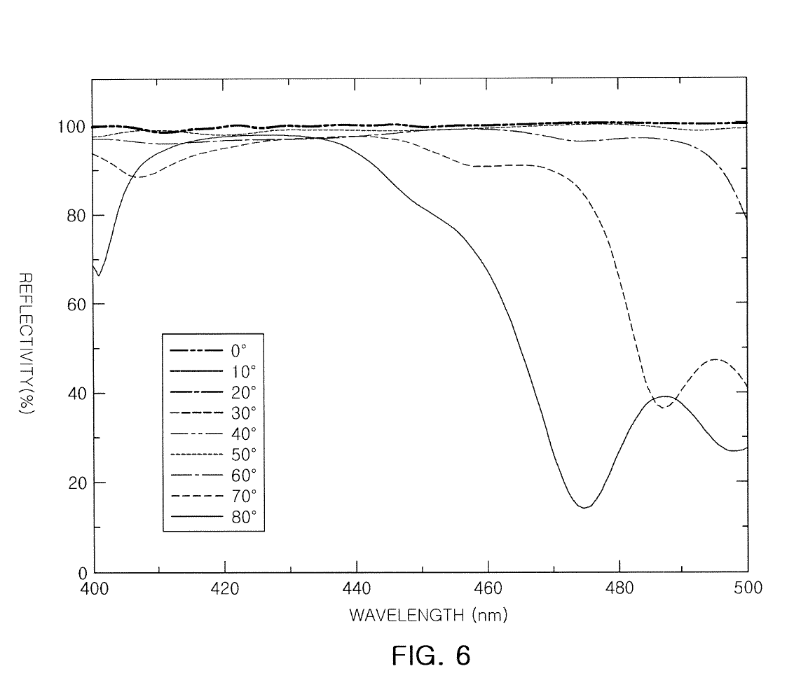

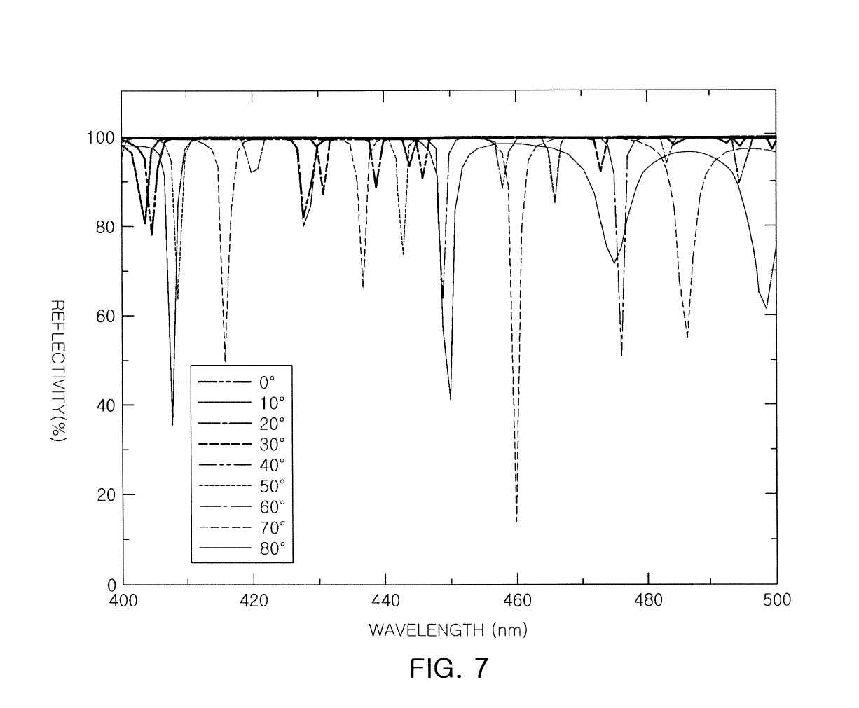

An aluminum metal reflective film was additionally deposited on one surface of on of the two DBR structures. Reflectivity characteristics of the DBR structure and those of the combination of the DBR and metal reflective structure were measured by a degree of reflectivity over each wavelength based on an incident angle, the results of which are illustrated in FIGS. 6 and 7.

As illustrated in FIGS. 6 and 7, when an incident angle was small (approximately 50° or less), there was no significant difference, but when an incident angle was large, in the case of using only the DBR structure, reflectivity was greatly changed over a wavelength band such that the reflectivity was greatly lowered in a wavelength band equal to or greater than 440 nm, while in the case of the combination of the DBR and Al reflective film (Al) (FIG. 7), a high degree of reflectivity was maintained on the whole without a great change based on an incident angle.

Thus, it can be seen that, when the metal reflective film is combined to the DBR structure, a change in the reflectivity based on a wavelength and an incident angle is reduced, obtaining excellent reflectivity characteristics on the whole, in comparison to the case of using the DBR structure alone.

### Experimental Example 2

### Effect of Combination of DBR+Metal Reflective Film

As discussed above, even when the anti-diffusion film 59 or the eutectic metal layer 59 is directly applied without the metal reflective film 55 made of material, such as aluminum (Al) or silver (Ag), having a high degree of reflectivity, desired reflectivity characteristics cannot be expected, and such an effect may be ascertained through an embodiment example and a comparative example as follows.

### Embodiment Example

First, the same DBR structure as that of the experiment example 1 was formed on a lower surface (including a sloped surface) of a sapphire substrate of a nitride LED, and an Al metal reflective film was deposited. In addition, a Ti/Au anti-diffusion film and an Au—Sn bonding metal layer were formed as a bonding laminate.

The LED chip fabricated thusly was bonded to a silicon submount substrate by using a bonding metal layer to fabricate a light emitting device having a structure similar to that illustrated in FIG. 5.

### Comparative Example

### Comparative Example

In another example, a nitride semiconductor light emitting device chip was fabricated in a similar manner to that of the embodiment example, except that a Ti/Au was formed on the DBR structure without depositing an Al metal reflective film, and subsequently, the LED chip was bonded to a silicon submount substrate by using the Au—Sn bonding metal layer to fabricate a white light emitting device.

Optical characteristics such as color temperature, color coordinates (or chromaticity) together with luminous flux of the light emitting device according to the embodiment example and that of the comparative example were measured. Table 2 below shows the measurement results.

TABLE 2

| | Vf | Luminous flux | Color temperature | | |
|---|---|---|---|---|---|
| Classification | (V) | (lm) | (CCT) | x | y |
| Embodiment | 3.39 | 104.9 | 4584 | 0.366 | 0.412 |
| example | | | | | |
| Comparative | 3.38 | 94.2 | 4593 | 0.366 | 0.414 |
| example | | | | | |

As shown in Table 2, color characteristics such as color temperature or color coordinates of the embodiment example and the comparative example were similar or the same, but the luminous flux of the embodiment example was 104.9 lm and that of the comparative example was 94.2 lm, showing a difference of approximately 10% under the same condition.

Such a difference was considered to result from the bonding a general metal layer used for an anti-diffusion film, rather than a metal reflective film such as Al having a high degree of reflectivity, to the rear surface of the DBR structure. Thus, as stated above, it can be confirmed that the structure of the combination of DBR and metal reflective film having a high degree of reflectivity guarantees high luminous flux also in an actual package structure.

A third aspect of the present invention provides a method for manufacturing a semiconductor LED chip.

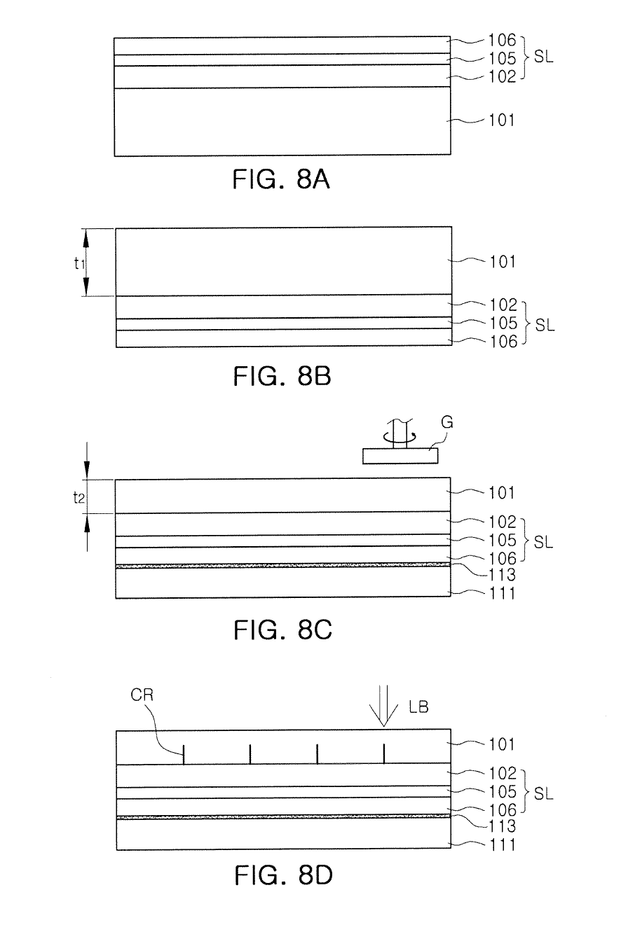

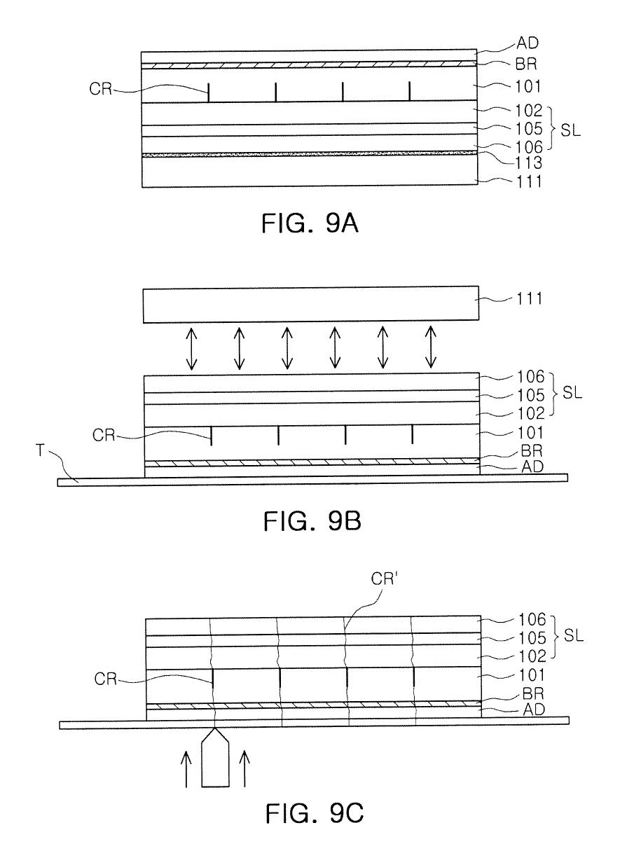

FIGS. 8 and 9 are cross-sectional views sequentially showing major processes of an example of a method for manufacturing an LED chip according to an embodiment of the present invention.

Referring to FIG. 8(a), according to a method for manufacturing an LED chip according to an embodiment of the present invention, first, a light-transmissive wafer 101 is prepared and a semiconductor laminate SL is subsequently formed on an upper surface of the light-transmissive wafer 101.

The light-transmissive wafer 101 may be a sapphire wafer. The semiconductor laminate SL includes a first conductivity-type semiconductor layer 102, an active layer 105, and a second conductivity-type semiconductor layer 106 sequentially formed on the light-transmissive wafer 101. The first and second conductivity types may be any one of different n type and p type, respectively. For example, the first conductivity-type semiconductor layer 102 may be an n-type semiconductor layer, and the second conductivity-type semiconductor layer 106 may be a p-type semiconductor layer.

Although not illustrated in detail in FIG. 8, the semiconductor laminate SL may have a first conductivity-type semiconductor layer region exposed through mesa-etching by respective device units. Also, first and second electrodes may be formed on an exposed region of the first conductivity-type semiconductor layer and the second conductivity-type semiconductor layer, respectively, of the respective device units.

Subsequently, as illustrated in FIG. 8(b), a support substrate 111 is provided on the semiconductor laminate SL.

The support substrate 111 may be a glass substrate, but the present invention is not limited thereto. Preferably, the support substrate 111 may be bonded to the semiconductor laminate SL by using a curable bonding resin 113.

A bonding process employed in a specific example will be described in detail. A thermosetting bonding resin is coated on the semiconductor laminate SL through a process such as spin coating, or the like, and a light-heat conversion layer made of a material that absorbs light energy and converts the same into heat is attached to the to a bonding target surface of the support substrate. Subsequently, the support substrate with the light-heat conversion layer attached thereto is bonded to a surface coated with the thermosetting bonding resin, and UV is irradiated thereto to cure the thermosetting bonding resin to bond the support substrate 111 and the semiconductor laminate SL.

Thereafter, as illustrated in FIG. 8(c), the light-transmissive wafer 101 having a large thickness t1 is polished to have a relatively small thickness t2. In case of using a sapphire substrate as the light-transmissive wafer 101, the sapphire substrate has a relatively large thickness of 600 μm or greater, so it is polished to have a thickness of 150 μm or less. Although the sapphire substrate is polished to have a smaller thickness, since it is maintained by the support substrate, breaking, or the like, during a handling process may be prevented.

Thereafter, as illustrated in FIG. 8(d), a laser beam LB is irradiated to form cracks CR to separate the light-transmissive wafer 101 and the semiconductor laminate SL into device units.

A scribing process employed in the present embodiment may be performed in a manner of forming cracks within a crystal such as wafer, or the like, rather than forming a physical groove by using a laser beam. In detail, as the laser beam LB, a stealth laser having a relatively long wavelength, e.g., a wavelength of about 800 nm to 1200 nm.

A laser absorption region may be prepared in advance to absorb stealth laser. The laser absorption region may be made of a metal or an alloy. Besides, any materials may be used as long as it can absorb laser, and for example, the laser absorption region may be made of a material such as carbon (C), copper (Cu), titanium (Ti), or the like.

When the stealth laser is irradiated from a lower surface of the light-transmissive wafer, cracks may be generated in the semiconductor laminate or the substrate corresponding to a laser absorption region positioned on a surface opposing the lower surface, and a final device separation process may be easily executed by using the cracks (Please see FIG. 8(g)).

The use of the process of forming cutting cracks by using a stealth laser L can significantly reduce a problem of adsorption of debris to a surface of the light emitting structure or a change in a crystal structure of a material forming the light emitting structure.

Also, since this process is performed such that cracks are internally generated without a physical separation on the lower surface of the light-transmissive wafer, as illustrated in FIG. 8(e), a process of depositing a reflective layer, or the like, on a lower surface of the light-transmissive wafer can be easily implemented.

Referring to FIG. 9(a), a process of forming a rear reflective laminate and a bonding laminate on a light-transmissive substrate is illustrated.

As described above with reference to FIG. 1, the rear reflective laminate BR may include the auxiliary optical layer 23 made of a material having a predetermined refractive index and a metal reflective layer 25 formed on a lower surface of the auxiliary optical layer 23. The optical auxiliary layer 23 employed in the present embodiment may be made of a material having a predetermined refractive index while having light transmittance. For example, the auxiliary optical layer 23 may be made of an oxide or a nitride including an element selected from the group consisting of silicon (Si), zirconium (Zr), tantalum (Ta), titanium (Ti), indium (In), tin (Sn), magnesium (Mg), and aluminum (Al). Meanwhile, the metal reflective film 25 may be made of aluminum (Al), silver (Ag), or a mixture thereof.

Also, as described above with reference to FIG. 1, the bonding laminate AD includes a bonding metal layer 27 made of a eutectic metal material and an anti-diffusion film 29 formed to prevent diffusion of elements between the bonding metal layer 27 and the metal reflective film 25.

A eutectic metal material of the bonding metal layer 27 may include at least one of gold (Au), silver (Ag), and tin (Sn). Preferably, the eutectic metal material of the bonding metal layer 27 may include Au—Sn.

Since the method for manufacturing a semiconductor LED chip according to an embodiment of the present invention has unique features in the aspect of a fabrication process such as the process of separating the light-transmissive wafer and the semiconductor laminate into device units, it is not limited to the rear reflective laminate and the bonding laminate. Namely, even a case of forming only the metal reflective film may be considered to be within the scope of the present invention.

Subsequently, as illustrated in FIG. 9(b), after irradiating the laser beam LB, an operation of removing the support substrate 111 may be additionally performed.

As illustrated, before removing the support substrate 111, an adhesive tape T may be attached to an upper surface of the semiconductor laminate facing downwardly. In the present embodiment, by performing the process of attaching the adhesive tape T before the separation process illustrated in FIG. 8(g), easy implementation of the separation process by device units may be guaranteed.

Thereafter, as illustrated in FIG. 9(c), the light-transmissive wafer 101 and the semiconductor laminate SL are separated by device units by using the cracks CR.

As described above with reference to FIG. 8(d), the separation process may be easily conducted by the crack components prepared in advance. Namely, as impact is applied to positions adjacent to the cracks by using a known unit such as a cutter, or the like, cracks may propagate to separate the light-transmissive wafer and the semiconductor laminate into device units. In this process, since the elements such as the metal reflective layer, or the like, prepared in FIG. 8(e) are provided as a thin film, they may also be separated in this cutting process.

In this manner, since cracks are generated by using a long wavelength laser such as the stealth laser, or the like, and used for the cutting process, debris, disadvantageous optically, may not be generated on the cut surface, unlike a scribing process using a UV laser.

As set forth above, according to embodiments of the invention, by combining the metal reflective film and the auxiliary optical film, a high degree of reflection efficiency can be guaranteed and substantial luminance can be increased in a desired direction. Also, since the eutectic alloy bonding layer is employed as a bonding member employed on the interface of the element bonded to the semiconductor LED chip, heat dissipation characteristics can be improved.

According to another aspect of the present invention, the LED chip employing a reflective film structure can be easily manufactured in the wafer level.

While the present invention has been shown and described in connection with the embodiments, it will be apparent to those skilled in the art that modifications and variations can be made without departing from the spirit and scope of the invention as defined by the appended claims.

What is claimed is:

1. A semiconductor light emitting diode (LED) chip comprising:
a semiconductor light emitting diode unit including a light-transmissive substrate, and a first conductivity-type semiconductor layer, an active layer, and a second conductivity-type semiconductor layer sequentially formed on an upper surface of the light-transmissive substrate;
a rear reflective laminate including an auxiliary optical layer formed on a lower surface of the light-transmissive substrate and made of a material having a predetermined refractive index and a metal reflective film formed on a lower surface of the auxiliary optical layer; and
a bonding laminate provided on a lower surface of the rear reflective laminate and including a bonding metal layer made of a eutectic metal material and an anti-diffusion film formed to prevent diffusion of elements between the bonding metal layer and the metal reflective film.

2. The semiconductor LED chip of claim 1, wherein the eutectic metal material of the bonding metal layer contains at least one among gold (Au), silver (Ag), and tin (Sn).

3. The semiconductor LED chip of claim 2, wherein the eutectic metal material of the bonding metal layer includes Au—Sn.

4. The semiconductor LED chip of claim 1, wherein the metal reflective film includes aluminum (Al), silver (Ag), or a mixture thereof.

5. The semiconductor LED chip of claim 1, wherein the anti-diffusion film includes a material selected from among chromium (Cr), gold (Au), TiW, TiN, and a combination thereof.

6. The semiconductor LED chip of claim 1, wherein the auxiliary optical layer is made of an oxide or a nitride including an element selected from the group consisting of silicon (Si), zirconium (Zr), tantalum (Ta), titanium (Ti), indium (In), tin (Sn), magnesium (Mg), and aluminum (Al).

7. The semiconductor LED chip of claim 1, wherein the auxiliary optical layer has a distributed Bragg reflector (DBR) structure in which two types of dielectric thin films having different refractive indices are alternately laminated.

8. The semiconductor LED chip of claim 7, wherein the two types of dielectric thin films are made of an oxide or a nitride including an element selected from the group consisting of silicon (Si), zirconium (Zr), tantalum (Ta), titanium (Ti), indium (In), tin (Sn), magnesium (Mg), and aluminum (Al), respectively.

9. A semiconductor light emitting device comprising a semiconductor light emitting diode (LED) chip and a support supporting the semiconductor LED chip,
wherein the semiconductor LED chip comprises:
a semiconductor light emitting diode unit including a light-transmissive substrate, and a first conductivity-type semiconductor layer, an active layer, and a second conductivity-type semiconductor layer sequentially formed on an upper surface of the light-transmissive substrate;
a rear reflective laminate including an auxiliary optical layer formed on a lower surface of the light-transmissive substrate and made of a material having a predetermined refractive index and a metal reflective film formed on a lower surface of the auxiliary optical layer; and
a bonding laminate provided on a lower surface of the rear reflective laminate and including a bonding metal layer having an interface fusion-bonded to the support and made of a eutectic metal material and an anti-diffusion film formed to prevent diffusion of elements between the bonding metal layer and the metal reflective film.

10. The semiconductor light emitting device of claim 9, wherein the eutectic metal material of the bonding metal layer contains at least one among gold (Au), silver (Ag), and tin (Sn).

11. The semiconductor light emitting device of claim 10, wherein the eutectic metal material of the bonding metal layer includes Au—Sn.

12. The semiconductor light emitting device of claim 9, wherein the metal reflective film includes aluminum (Al), silver (Ag), or a mixture thereof.

13. The semiconductor light emitting device of claim 9, wherein the anti-diffusion film includes a material selected from among chromium (Cr), gold (Au), TiW, TiN, and a combination thereof.

14. The semiconductor light emitting device of claim 9, wherein the auxiliary optical layer is made of an oxide or a nitride including an element selected from the group consisting of silicon (Si), zirconium (Zr), tantalum (Ta), titanium (Ti), indium (In), tin (Sn), magnesium (Mg), and aluminum (Al).

15. The semiconductor light emitting device of claim 9, wherein the auxiliary optical layer has a distributed Bragg reflector (DBR) structure in which two types of dielectric thin films having different refractive indices are alternately laminated.

16. The semiconductor light emitting device of claim 15, wherein the two types of dielectric thin films are made of an oxide or a nitride including an element selected from the group consisting of silicon (Si), zirconium (Zr), tantalum (Ta), titanium (Ti), indium (In), tin (Sn), magnesium (Mg), and aluminum (Al), respectively.

17. A method for manufacturing a semiconductor light emitting diode (LED) chip, the method comprising:
preparing a light-transmissive wafer and a semiconductor laminate including a first conductivity-type semiconductor layer, an active layer, and a second conductivity-type semiconductor layer sequentially formed on an upper surface of the light-transmissive wafer;
providing a support substrate on the semiconductor laminate;
polishing a lower surface of the light-transmissive wafer to reduce a thickness of the light-transmissive wafer;
irradiating a laser beam to form cracks allowing the light-transmissive wafer and the semiconductor laminate to be separated into device units;
forming a metal reflective film on a lower surface of the light-transmissive wafer after the irradiating a laser beam; and
separating the light-transmissive wafer and the semiconductor laminate by using the cracks.

18. The method of claim 17, further comprising forming an auxiliary optical layer made of a material having a predetermined refractive index on a lower surface of the light-transmissive substrate, between the irradiating of a laser beam and the forming of the metal reflective film.

19. The method of claim 17, further comprising forming a bonding laminate on the metal reflective film, the bonding laminate including a bonding metal layer made of a eutectic metal material and an anti-diffusion film formed to prevent diffusion of elements between the bonding metal layer and the metal reflective film, between the forming of the metal reflective film and the separating of the light-transmissive wafer and the semiconductor laminate.

20. The method of claim 17, further comprising removing the support substrate from the semiconductor laminate, before the separating of the light-transmissive wafer and the semiconductor laminate.
